(19) United States
(12) Patent Application Publication
(10) Pub. No.: US 2026/0193812 A1
(43) Pub. Date: Jul. 9, 2026

(54) SINGLE-CRYSTAL CATHODE MATERIAL MODIFIED BY MOLTEN SALT-ASSISTED VALENCE GRADIENT DOPING, PREPARATION METHOD THEREFOR, AND USE THEREOF

(71) Applicant: Kunming University Of Science And Technology, Kunming (CN)

(72) Inventors: Yannan ZHANG, Kunming (CN); Peng DONG, Kunming (CN); Yingjie ZHANG, Kunming (CN); Bao ZHANG, Kunming (CN); Enfeng ZHANG, Kunming (CN)

(73) Assignee: Kunming University Of Science And Technology, Kunming (CN)

(21) Appl. No.: 19/550,289

(22) Filed: Feb. 26, 2026

Related U.S. Application Data
(63) Continuation of application No. PCT/CN2024/137342, filed on Dec. 6, 2024.

(30) Foreign Application Priority Data
Sep. 2, 2024 (CN) 202411219587.5

(51) Int. Cl. C30B 31/04; C30B 1/12; C30B 29/22; C30B 33/02; H01M 4/505

(52) U.S. Cl. CPC C30B 31/04; C30B 1/12; C30B 29/22; C30B 33/02; H01M 4/505

(57) ABSTRACT

A single-crystal cathode material modified by molten salt-assisted valence gradient doping, a preparation method therefor, and use thereof are provided. The preparation method includes the following steps: mixing a transition metal source, a lithium source, a manganese source and a molten salt additive, sequentially performing first sintering and second sintering, and removing the molten salt additive to obtain a doped and modified single-crystal cathode material precursor; tempering the doped and modified single-crystal cathode material precursor to obtain a single-crystal cathode material modified by molten salt-assisted valence gradient doping. The doped and modified single-crystal cathode material may effectively avoid the capacity loss of the material, significantly reduce the lattice mismatch in the lithium deintercalation/intercalation process and relieve the volume strain in the charge and discharge process. Meanwhile, the formed M-O bonds can enhance the structural stability of the material and inhibit the formation of microcracks in the material.

### CROSS REFERENCE TO THE RELATED APPLICATIONS

This application is a continuation application of International Application No. PCT/CN2024/137342, filed on December 6, 2024, which is based upon and claims priority to Chinese Patent Application No. 202411219587.5, filed on September 2, 2024, the entire contents of which are incorporated herein by reference.

### TECHNICAL FIELD

The present invention relates to the technical field of new energy materials, and in particular, to a single-crystal cathode material modified by molten salt-assisted valence gradient doping, a preparation method therefor, and use thereof.

### BACKGROUND

For a long time, excessive reliance on fossil energy production and consumption has led to disharmony and insecurity between energy and the environment, becoming a common problem faced by countries around the world. Due to the increasing concern of global energy systems based on fossil energy in terms of energy depletion and environmental pollution, there is an urgent need for renewable clean energy and energy conversion and storage systems adapted thereto.

Rechargeable lithium-ion batteries (LIBs) have the advantages of high output voltage, good safety performance and a long cycle life, and have become an important energy supply device for portable electronic products, electric vehicles and even large-scale energy storage systems. However, there are some obstacles to the development of LIBs, such as structural stability and surface side reactions of the cathode material. Spinel LiMn₂O₄ cathode materials have attracted much attention due to the advantages such as stable skeleton, three-dimensional diffusion channels of Li, low Coulomb repulsion and good thermal stability, as well as the outstanding advantages such as abundant reserves of Mn element, non-toxicity and environmental protection. Despite the significant advantages of the spinel structure, the capacity decay of LiMn₂O₄ is a fatal defect, especially in high temperature environments, where LiMn₂O₄ is subjected to the following changes: (1) Jahn-Taller distortion of Mn³⁺ during deep discharge; (2) Mn³⁺ disproportionation reaction (Mn³⁺→Mn⁴⁺+Mn²⁺) leads to the dissolution loss of manganese, and the large-scale dissolution loss of active manganese ions leads to an irreversible decrease in specific capacity; (3) HF is produced by the decomposition of the electrolyte, corroding the electrode; (4) Oxygen defects are caused by the material synthesis process and/or electrolyte decomposition; (5) Irreversible phase change triggers the formation of microcracks; (6) The deposition of manganese on the negative electrode leads to the destruction of the solid electrolyte interphase (SEI) and the increase of impedance.

### SUMMARY

An objective of the present invention is to provide a single-crystal cathode material modified by molten salt-assisted valence gradient doping, a preparation method therefor, and use thereof, so as to solve the Jahn-Taller distortion of Mn³⁺, Mn³⁺ disproportionation reaction and other phenomena produced by the traditional unmodified spinel LiMn₂O₄ cathode materials, thereby leading to capacity decay.

To achieve the above objective, the present invention provides the following technical solutions.

The present invention provides a preparation method for a single-crystal cathode material modified by molten salt-assisted valence gradient doping, which includes the following steps:

(1) mixing a transition metal source, a lithium source, a manganese source and a molten salt additive, sequentially performing first sintering and second sintering, and removing the molten salt additive to obtain a doped and modified single-crystal cathode material precursor; and

(2) tempering the doped and modified single-crystal cathode material precursor to obtain a single-crystal cathode material modified by molten salt-assisted valence gradient doping;

wherein the transition metal source in the step (1) is a transition metal oxide containing one or more doping elements of Mg²⁺, Sm³⁺, Ti⁴⁺, Nb⁵⁺, and Mo⁶⁺.

Preferably, in the step (1), the lithium source includes LiOH·H₂O or Li₂CO₃, the manganese source includes MnCO₃, Mn₃O₄ or MnO₂, and the molten salt additive is Li₂SO₄·H₂O.

Preferably, in the step (1), a molar ratio of the transition metal source, the lithium source, the manganese source, and the molten salt additive is 0.01:(1-1.08):2:(1-2).

Preferably, in the step (1), the mixing is ball milling; and the ball milling is performed for 3-6 h at a rotation speed of 300-400 r/min, and a ball-to-material ratio is 10-20:1.

Preferably, in the step (1), the first sintering is performed at a temperature of 400-500 °C for 3-6 h, and a rate of heating to the temperature required for the first sintering is 1.5-3 °C/min.

Preferably, in the step (1), the second sintering is performed at a temperature of 750-850 °C for 10-14 h, and a rate of heating to the temperature required for the second sintering is 1.5-3 °C/min.

Preferably, in the step (1), an atmosphere of the first sintering and the second sintering is an oxygen atmosphere.

Preferably, in the step (2), the tempering is performed at a temperature of 700-750 °C for 4-6 h, and a rate of heating to the temperature required for the tempering is 1.5-3 °C/min.

The present invention further provides a single-crystal cathode material modified by molten salt-assisted valence gradient doping prepared by the preparation method.

The present invention further provides use of the single-crystal cathode material modified by molten salt-assisted valence gradient doping in a lithium-ion battery.

It can be known from the technical solutions that, compared with the prior art, the present invention has the following beneficial effects.

(1) According to the present invention, molten salt is used to assist in doping transition metal elements into the lithium manganese oxide cathode material. The molten salt may provide a molten liquid environment during the sintering process, allowing the transition metal doping elements to be evenly distributed inside the material. In subsequent treatments, the molten salt may be completely removed by washing, and finally a single-crystal material modified by doping with different valence gradients is synthesized. If the molten salt is not removed, pure lithium manganese oxide material cannot be synthesized, and the final product contains impurity phases. The process of removing molten salt causes defects on the material surface. The tempering treatment may repair the surface structure of the material and remove excess moisture.

(2) The doped and modified single-crystal cathode material prepared by the present invention may effectively avoid the capacity loss of the material, significantly reduce the lattice mismatch during the lithium deintercalation/intercalation process, and alleviate the volume strain during the charge and discharge process. Meanwhile, the formed M-O bonds (M refers to transition metal) can enhance the structural stability of the material and inhibit the formation of microcracks in the material. Bulk doping may enhance the structural stability of the material without changing the basic framework of the material, including the adjustment of the bulk and interface structure; in addition, bulk doping may effectively improve the diffusion dynamics of lithium ions, significantly reduce the Li transmission barrier, and increase the ion transport rate. The preparation method of the cathode material of the present invention is applicable to existing preparation methods of cathode materials, such as solid phase method and wet chemical method, is convenient for industrial application, and provides ideas for commercial modification of cathode materials.

(3) The cycle stability of the lithium-ion battery prepared using the cathode material of the present invention is significantly increased, and the side reactions on the electrode surface are suppressed. Moreover, the number of charge and discharge cycles of the obtained battery is significantly improved, and the energy density, safety, and reliability of this lithium-ion battery are significantly better than those of unmodified lithium-ion batteries of the same type and model, which is conducive to commercial application.

(4) The single-crystal cathode material modified by molten salt-assisted valence gradient doping provided by the present invention does not increase the cost of lithium-ion battery preparation, and the production equipment involved is simple, the production cycle is short, the process is simple, and this single-crystal cathode material is suitable for large-scale production.

(5) The doping modification method of the present invention has a wide range of adaptability and is applicable to lithium manganese oxide, lithium nickel manganese oxide, lithium-rich manganese-based cathode materials, lithium cobalt oxide, ternary layered materials, or lithium iron phosphate cathode materials.

### BRIEF DESCRIPTION OF THE DRAWINGS

To more clearly illustrate the technical solutions in the examples of the present invention or in the prior art, the drawings used in the description of the examples or the prior art are briefly introduced below.

FIG. 1 is a schematic diagram of a process for preparing a single-crystal cathode material modified by molten salt-assisted valence gradient doping;

FIG. 2 is an XRD pattern of cathode materials obtained in Examples 1 to 5 and Comparative Example 1; and

FIG. 3 shows cycle performance test results of batteries obtained in Application Examples 1 to 5 and Comparative Application Example 1.

### DETAILED DESCRIPTION OF THE EMBODIMENTS

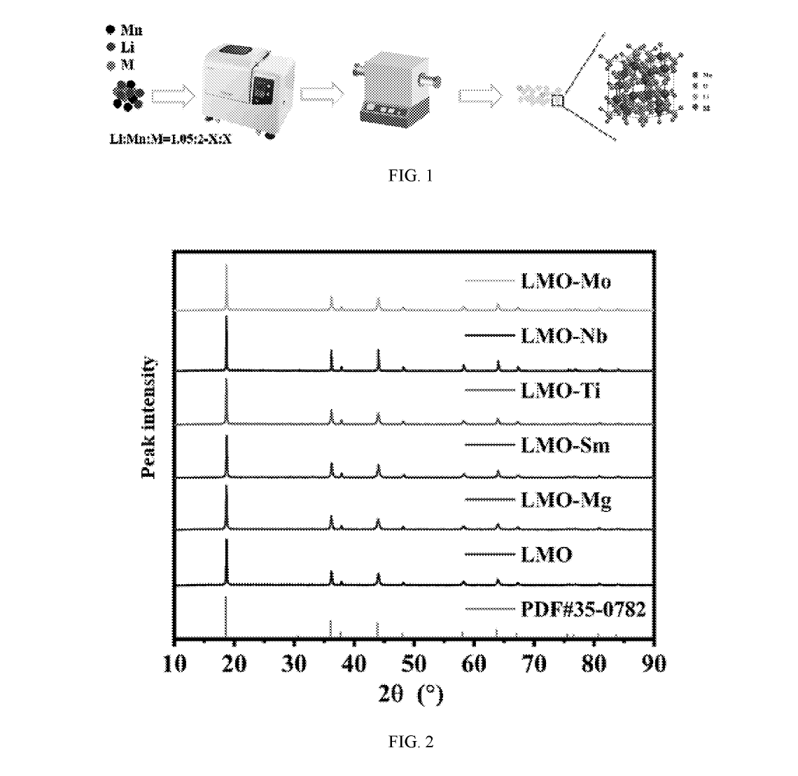

The present invention provides a preparation method for a single-crystal cathode material modified by molten salt-assisted valence gradient doping, which includes the following steps, as shown in FIG. 1:

(1) mixing a transition metal source, a lithium source, a manganese source and a molten salt additive, sequentially performing first sintering and second sintering, and removing the molten salt additive to obtain a doped and modified single-crystal cathode material precursor; and

(2) tempering the doped and modified single-crystal cathode material precursor to obtain a single-crystal cathode material modified by molten salt-assisted valence gradient doping;

wherein the transition metal source in the step (1) is a transition metal oxide containing one or more doping elements of Mg²⁺, Sm³⁺, Ti⁴⁺, Nb⁵⁺, and Mo⁶⁺.

In the present invention, The transition metal source in the step (1) is preferably a transition metal oxide containing Mg²⁺, Sm³⁺, Ti⁴⁺, Nb⁵⁺ or Mo⁶⁺ doping elements, further preferably a transition metal oxide containing Ti⁴⁺, Nb⁵⁺ or Mo⁶⁺ doping elements, and more preferably a transition metal oxide containing Mo⁶⁺ doping elements.

In the present invention, the lithium source in the step (1) preferably includes LiOH·H₂O or Li₂CO₃.

In the present invention, the manganese source in the step (1) preferably includes MnCO₃, Mn₃O₄ or MnO₂, and further preferably includes MnCO₃ or Mn₃O₄.

In the present invention, the molten salt additive in the step (1) is preferably Li₂SO₄·H₂O.

In the present invention, a molar ratio of the transition metal source, the lithium source, the manganese source, and the molten salt additive in the step (1) is preferably 0.01:(1-1.08):2:(1-2), further preferably 0.01:(1.02-1.06):2:(1.2-1.6), and more preferably 0.01:1.05:2:1.4.

In the present invention, the mixing in the step (1) is preferably ball milling.

In the present invention, the ball milling equipment is preferably a planetary ball mill.

In the present invention, the time of the ball milling is preferably 3-6 h, further preferably 4-5 h, and more preferably 4 h; the rotation speed is preferably 300-400 r/min, further preferably 350-400 r/min, and more preferably 400 r/min; and a ball material ratio is preferably 10-20:1, further preferably 10-15: 1, and more preferably 10:1.

In the present invention, the grinding balls used in the ball milling are preferably zirconia grinding balls.

In the present invention, the device for the first sintering and the second sintering in the step (1) is preferably a tubular furnace.

In the present invention, the temperature of the first sintering in the step (1) is preferably 400-500°C, further preferably 450-500 °C, and more preferably 450 °C; the time is preferably 3-6 h, further preferably 4-5 h, and more preferably 4 h; and a rate of heating to the temperature required for the first sintering is preferably 1.5-3 °C/min, further preferably 2-3°C/min, and more preferably 2.5 °C/min.

In the present invention, the temperature of the second sintering in the step (1) is preferably 750-850 °C, further preferably 780-850 °C, and more preferably 800 °C; the time is preferably 10-14 h, further preferably 12-13 h, and more preferably 12 h; and a rate of heating to the temperature required for the second sintering is preferably 1.5-3 °C/min, further preferably 2-3 °C/min, and more preferably 2.5 °C/min.

In the present invention, an atmosphere of the first sintering and the second sintering in the step (1) is preferably an oxygen atmosphere.

In the present invention, the step (1) preferably includes cooling after the second sintering. There is no limitation on the cooling conditions, and any method known to those skilled in the art may be used.

In the present invention, the method for removing the molten salt additive in the step (1) is preferably washing.

In the present invention, the washing agent is preferably water. There is no limitation on the number of washing times and the temperature of the water, which may be adjusted according to requirements.

In the present invention, the device for the tempering treatment in step (2) is preferably a tubular furnace.

In the present invention, the tempering temperature in the step (2) is preferably 700-750 °C, further preferably 725-750 °C, and more preferably 725 °C; the time is preferably 4-6 h, further preferably 5-6 h, and more preferably 6 h; and a rate of heating to the temperature required for the tempering treatment is preferably 1.5-3 °C/min, further preferably 2-3 °C/min, and more preferably 2.5 °C/min.

In the present invention, the atmosphere for the tempering treatment in the step (2) is preferably an oxygen atmosphere.

In the present invention, the step (2) preferably includes cooling after the tempering treatment. There is no limitation on the cooling conditions, and any method known to those skilled in the art may be used.

The present invention further provides a single-crystal cathode material modified by molten salt-assisted valence gradient doping prepared by the preparation method.

The present invention further provides use of the single-crystal cathode material modified by molten salt-assisted valence gradient doping in a lithium-ion battery.

In the present invention, the application method is not limited, and any method well known to those skilled in the art may be used.

In the present invention, the lithium-ion battery is preferably a CR2025 button battery.

In the present invention, the lithium-ion battery preferably includes a positive electrode plate, a negative electrode plate, a separator, and an electrolyte.

In the present invention, a method for preparing the positive electrode plate preferably includes the following steps:

mixing a single-crystal cathode material modified by molten salt-assisted valence gradient doping, conductive carbon black, a binder and an organic solvent to obtain a positive electrode slurry; coating the positive electrode slurry on aluminum foil, drying in a vacuum drying oven, and cutting to obtain the positive electrode plate.

In the present invention, the binder is preferably polyvinylidene fluoride (PVDF).

In the present invention, the organic solvent is preferably N-methylpyrrolidone (NMP).

In the present invention, the mass ratio of the single-crystal cathode material modified by molten salt-assisted valence gradient doping, the conductive carbon black and the binder is not limited, and a solution well known to those skilled in the art may be used. Specifically, in this embodiment of the present invention, the mass ratio of the single-crystal cathode material modified by molten salt-assisted valence gradient doping, the conductive carbon black and the binder is preferably 8:1:1.

In the present invention, the mixing method is preferably grinding. The grinding time is preferably 15-30 min, further preferably 20-30 min, and more preferably 25 min.

In the present invention, the drying temperature is preferably 80-120 °C, further preferably 80-100 °C, and more preferably 90 °C; the drying time is preferably 10-12 h, further preferably 11-12 h, and more preferably 12 h.

In the present invention, the negative electrode plate is preferably a lithium plate.

In the present invention, the separator is preferably a Celgard 2400 separator.

In the present invention, the electrolyte is preferably 1 M LiPF₆ DMC:EC=7:3 wt% 5%FEC.

The technical solutions in the examples of the present invention will be clearly and completely described below. Apparently, the described examples are merely a part, rather than all of the examples of the present invention. Based on the examples of the present invention, all other examples obtained by those of ordinary skill in the art without creative efforts shall fall within the protection scope of the present invention.

### Example 1

This example provides a method for preparing a molten salt-assisted magnesium-doped modified single-crystal cathode material, which includes the following steps:

(1) MgO, LiOH·H₂O, MnCO₃ and Li₂SO₄·H₂O were placed in a ball milling tank according to a molar ratio of 0.01:1.02:2:1.5, and ball milled for 3 h in a planetary ball mill at 350 r/min and a ball-to-material ratio of 15:1 using zirconia grinding balls. The ball-milled mixture was placed in a crucible, and oxygen atmosphere was introduced into a tubular furnace, the temperature was increased to 450 °C at 2.5 °C/min and kept at this temperature for 5 h, then increased to 780 °C at 2.5 °C/min and kept at this temperature for 12 h, and then cooled with the furnace. The obtained product was washed in 50 °C water 5 times to remove the molten salt therein, thereby obtaining a magnesium-doped modified single-crystal cathode material precursor.

(2) The magnesium-doped modified single-crystal cathode material precursor was placed in a tubular furnace, an oxygen atmosphere was introduced, the precursor was heated to 725 °C at a rate of 2.5 °C/min, annealed for 6 h, and cooled with the furnace to obtain the molten salt-assisted magnesium-doped modified single-crystal cathode material, which was marked as LMO-Mg.

### Example 2

This example provides a method for preparing a molten salt-assisted samarium-doped modified single-crystal cathode material, which includes the following steps:

(1) Sm₂O₃, Li₂CO₃, Mn₃O₄ and Li₂SO₄·H₂O were placed in a ball milling tank according to a molar ratio of 0.01:1.05:2:1.2, and ball milled for 4 h in a planetary ball mill at 400 r/min and a ball-to-material ratio of 10:1 using zirconia grinding balls. The ball-milled mixture was placed in a crucible, and oxygen atmosphere was introduced into a tubular furnace, the temperature was increased to 500 °C at 2 °C/min and kept at this temperature for 4 h, then increased to 800 °C at 2 °C/min and kept at this temperature for 12 h, and then cooled with the furnace. The obtained product was washed in 50 °C water 5 times to remove the molten salt therein, thereby obtaining a samarium-doped modified single-crystal cathode material precursor.

(2) The samarium-doped modified single-crystal cathode material precursor was placed in a tubular furnace, an oxygen atmosphere was introduced, the precursor was heated to 700 °C at a rate of 2 °C/min, annealed for 6 h, and cooled with the furnace to obtain the molten salt-assisted samarium-doped modified single-crystal cathode material, which was marked as LMO-Sm.

### Example 3

This example provides a method for preparing a molten salt-assisted titanium-doped modified single-crystal cathode material, which includes the following steps:

(1) TiO₂, LiOH·H₂O, MnO₂ and Li₂SO₄·H₂O were placed in a ball milling tank according to a molar ratio of 0.01:1.02:2:1.6, and ball milled for 6 h in a planetary ball mill at 300 r/min and a ball-to-material ratio of 12:1 using zirconia grinding balls. The ball-milled mixture was placed in a crucible, and oxygen atmosphere was introduced into a tubular furnace, the temperature was increased to 500 °C at 2 °C/min and kept at this temperature for 5 h, then increased to 850 °C at 2 °C/min and kept at this temperature for 10 h, and then cooled with the furnace. The obtained product was washed in 50 °C water 5 times to remove the molten salt therein, thereby obtaining a titanium-doped modified single-crystal cathode material precursor.

(2) The titanium-doped modified single-crystal cathode material precursor was placed in a tubular furnace, an oxygen atmosphere was introduced, the precursor was heated to 750 °C at a rate of 2 °C/min, annealed for 4 h, and cooled with the furnace to obtain the molten salt-assisted titanium-doped modified single-crystal cathode material, which was marked as LMO-Ti.

### Example 4

This example provides a method for preparing a molten salt-assisted niobium-doped modified single-crystal cathode material, which includes the following steps:

(1) Nb₂O₅, LiOH·H₂O, Mn₃O₄ and Li₂SO₄·H₂O were placed in a ball milling tank according to a molar ratio of 0.01:1.06:2:1.4, and ball milled for 5 h in a planetary ball mill at 300 r/min and a ball-to-material ratio of 15:1 using zirconia grinding balls. The ball-milled mixture was placed in a crucible, and oxygen atmosphere was introduced into a tubular furnace, the temperature was increased to 450 °C at 3 °C/min and kept at this temperature for 6 h, then increased to 800 °C at 3 °C/min and kept at this temperature for 13 h, and then cooled with the furnace. The obtained product was washed in 50 °C water 5 times to remove the molten salt therein, thereby obtaining a niobium-doped modified single-crystal cathode material precursor.

(2) The niobium-doped modified single-crystal cathode material precursor was placed in a tubular furnace, an oxygen atmosphere was introduced, the precursor was heated to 750 °C at a rate of 3 °C/min, annealed for 5 h, and cooled with the furnace to obtain the molten salt-assisted niobium-doped modified single-crystal cathode material, which was marked as LMO-Nb.

### Example 5

This example provides a method for preparing a molten salt-assisted molybdenum-doped modified single-crystal cathode material, which includes the following steps:

(1) MoO₃, LiOH·H₂O, MnCO₃ and Li₂SO₄·H₂O were placed in a ball milling tank according to a molar ratio of 0.01:1.05:2:1, and ball milled for 4 h in a planetary ball mill at 400 r/min and a ball-to-material ratio of 10:1 using zirconia grinding balls. The ball-milled mixture was placed in a crucible, and oxygen atmosphere was introduced into a tubular furnace, the temperature was increased to 450 °C at 1.5 °C/min and kept at this temperature for 4 h, then increased to 800 °C at 1.5 °C/min and kept at this temperature for 12 h, and then cooled with the furnace. The obtained product was washed in 50 °C water 5 times to remove the molten salt therein, thereby obtaining a molybdenum-doped modified single-crystal cathode material precursor.

(2) The molybdenum-doped modified single-crystal cathode material precursor was placed in a tubular furnace, an oxygen atmosphere was introduced, the precursor was heated to 725 °C at a rate of 1.5 °C/min, annealed for 5 h, and cooled with the furnace to obtain the molten salt-assisted molybdenum-doped modified single-crystal cathode material, which was marked as LMO-Mo.

### Comparative Example 1

This comparative example provides a method for preparing a single-crystal cathode material, which includes the following steps:

(1) LiOH·H₂O, MnCO₃ and Li₂SO₄·H₂O were placed in a ball milling tank according to a molar ratio of 1.08:2:2, and ball milled for 5 h in a planetary ball mill at 400 r/min and a ball-to-material ratio of 20:1 using zirconia grinding balls. The ball-milled mixture was placed in a crucible, and oxygen atmosphere was introduced into a tubular furnace, the temperature was increased to 480 °C at 3 °C/min and kept at this temperature for 4 h, then increased to 780 °C at 3 °C/min and kept at this temperature for 13 h, and then cooled with the furnace. The obtained product was washed in 50 °C water 5 times to remove the molten salt therein, thereby obtaining a single-crystal cathode material precursor.

(2) The single-crystal cathode material precursor was placed in a tubular furnace, an oxygen atmosphere was introduced, the precursor was heated to 700 °C at a rate of 3 °C/min, annealed for 5 h, and cooled with the furnace to obtain the single-crystal cathode material, which was marked as LMO.

The cathode materials obtained in Examples 1 to 5 and Comparative Example 1 were subjected to XRD testing, and the results are shown in FIG. 2. As shown in FIG. 2, the doped and modified lithium manganese oxide cathode material is the same as the lithium manganese oxide cathode material, without the generation of secondary phases and impurity peaks. All diffraction peaks point to the spinel LiMn₂O₄ standard card (JCPDS 35-0782), belonging to the Fd3m space group, and is a standard lithium manganese oxide cathode material.

### Application Examples 1 to 5, Comparative Application Example 1

(1) The cathode materials obtained in Examples 1 to 5 and Comparative Example 1, conductive carbon black (DodoChem, model super C65) and PVDF (a molecular weight of 1 million) were mixed and ground at a mass ratio of 8:1:1 for 30 min, NMP was added thereto, and the mixture was mixed to obtain a positive electrode slurry; the positive electrode slurry was uniformly coated on aluminum foil with a loading of 4 mg·cm⁻², dried in a vacuum drying oven at 80 °C for 12 h, and cut to obtain a positive electrode plate.

(2) The positive electrode plate, lithium plate, Celgard 2400 separator, and 1 M LiPF₆ DMC:EC=7:3 wt% 5% FEC electrolyte obtained in the step (1) were assembled into CR2025 button-type batteries.

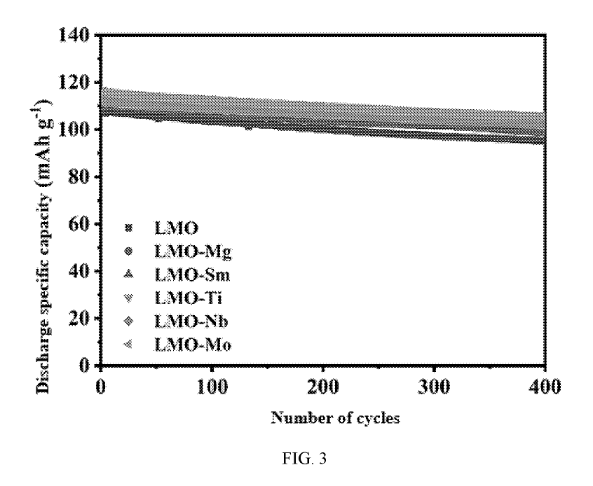

The assembled batteries of Application Examples 1 to 5 and Comparative Application Example 1 were placed in a blue-electricity test system for cycle performance testing. The results are shown in FIG. 3. As shown in FIG. 3, the doped and modified lithium manganese oxide cathode material has long cycle stability, which is much higher than the cycle retention rate of the undoped and modified lithium manganese oxide cathode material.

The above descriptions are only preferred embodiments of the present invention. It should be noted that those of ordinary skill in the art can also make several improvements and modifications without departing from the principle of the present invention, and such improvements and modifications shall fall within the protection scope of the present invention.

What is claimed is:

1. A preparation method for a single-crystal cathode material modified by molten salt-assisted valence gradient doping, comprising the following steps:
(1) mixing a transition metal source, a lithium source, a manganese source, and a molten salt additive, sequentially performing first sintering and second sintering, and removing the molten salt additive to obtain a doped and modified single-crystal cathode material precursor; and
(2) tempering the doped and modified single-crystal cathode material precursor to obtain the single-crystal cathode material modified by molten salt-assisted valence gradient doping;
wherein the transition metal source in the step (1) is a transition metal oxide containing one or more doping elements of Ti⁴⁺, Nb⁵⁺, and Mo⁶⁺;
or the transition metal source in the step (1) is a transition metal oxide containing one or more doping elements of Mg²⁺ and Sm³⁺;
the manganese source comprises MnCO₃, Mn₃O₄, or MnO₂;
in the step (1), a molar ratio of the transition metal source, the lithium source, the manganese source, and the molten salt additive is 0.01:(1-1.08):2:(1-2);
in the step (1), the mixing is ball milling; the ball milling is performed for 3-6 h at a rotation speed of 300-400 r/min, and a ball-to-material ratio is 10-20:1; and
in the step (2), the tempering is performed at a temperature of 700-750 °C for 4-6 h, and a rate of heating to the temperature required for the tempering is 1.5-3 °C/min.

2. The preparation method according to claim 1, wherein in the step (1), the lithium source comprises LiOH·H₂O or Li₂CO₃, and the molten salt additive is Li₂SO₄·H₂O.

3. The preparation method according to claim 1, wherein in the step (1), the first sintering is performed at a temperature of 400-500 °C for 3-6 h, and a rate of heating to the temperature required for the first sintering is 1.5-3 °C/min.

4. The preparation method according to claim 1, wherein in the step (1), the second sintering is performed at a temperature of 750-850 °C for 10-14 h, and a rate of heating to the temperature required for the second sintering is 1.5-3 °C/min.

5. The preparation method according to claim 4, wherein in the step (1), an atmosphere of the first sintering and the second sintering is an oxygen atmosphere.

6. A single-crystal cathode material modified by molten salt-assisted valence gradient doping prepared by the preparation method according to claim 1.

7. A method for preparing a lithium-ion battery, comprising using the single-crystal cathode material modified by molten salt-assisted valence gradient doping according to claim 6.

8. The preparation method according to claim 3, wherein in the step (1), the second sintering is performed at a temperature of 750-850 °C for 10-14 h, and a rate of heating to the temperature required for the second sintering is 1.5-3 °C/min.

9. The preparation method according to claim 8, wherein in the step (1), an atmosphere of the first sintering and the second sintering is an oxygen atmosphere.

10. The single-crystal cathode material modified by molten salt-assisted valence gradient doping according to claim 6, wherein in the step (1) of the preparation method, the lithium source comprises LiOH·H₂O or Li₂CO₃, and the molten salt additive is Li₂SO₄·H₂O.

11. The single-crystal cathode material modified by molten salt-assisted valence gradient doping according to claim 6, wherein in the step (1) of the preparation method, the first sintering is performed at a temperature of 400-500 °C for 3-6 h, and a rate of heating to the temperature required for the first sintering is 1.5-3 °C/min.

12. The single-crystal cathode material modified by molten salt-assisted valence gradient doping according to claim 6, wherein in the step (1) of the preparation method, the second sintering is performed at a temperature of 750-850 °C for 10-14 h, and a rate of heating to the temperature required for the second sintering is 1.5-3 °C/min.

13. The single-crystal cathode material modified by molten salt-assisted valence gradient doping according to claim 11, wherein in the step (1) of the preparation method, the second sintering is performed at a temperature of 750-850 °C for 10-14 h, and a rate of heating to the temperature required for the second sintering is 1.5-3 °C/min.

14. The single-crystal cathode material modified by molten salt-assisted valence gradient doping according to claim 12, wherein in the step (1) of the preparation method, an atmosphere of the first sintering and the second sintering is an oxygen atmosphere.

15. The single-crystal cathode material modified by molten salt-assisted valence gradient doping according to claim 13, wherein in the step (1) of the preparation method, an atmosphere of the first sintering and the second sintering is an oxygen atmosphere.

16. The method according to claim 7, wherein in the step (1) of the preparation method, the lithium source comprises LiOH·H₂O or Li₂CO₃, and the molten salt additive is Li₂SO₄·H₂O.

17. The method according to claim 7, wherein in the step (1) of the preparation method, the first sintering is performed at a temperature of 400-500 °C for 3-6 h, and a rate of heating to the temperature required for the first sintering is 1.5-3 °C/min.

18. The method according to claim 7, wherein in the step (1) of the preparation method, the second sintering is performed at a temperature of 750-850 °C for 10-14 h, and a rate of heating to the temperature required for the second sintering is 1.5-3 °C/min.

19. The method according to claim 17, wherein in the step (1) of the preparation method, the second sintering is performed at a temperature of 750-850 °C for 10-14 h, and a rate of heating to the temperature required for the second sintering is 1.5-3 °C/min.

20. The method according to claim 18, wherein in the step (1) of the preparation method, an atmosphere of the first sintering and the second sintering is an oxygen atmosphere.
